(19) United States
(12) Patent Application Publication
(10) Pub. No.: US 2006/0056227 A1
(43) Pub. Date: Mar. 16, 2006

(54) One time programmable phase change memory

(76) Inventor: Ward D. Parkinson, Boise, ID (US)

Correspondence Address: TROP PRUNER & HU, PC, 8554 KATY FREEWAY, SUITE 100, HOUSTON, TX, 77024, US

(21) Appl. No.: 10/939,142

(22) Filed: Sep. 10, 2004

(51) Int. Cl. G11C 11/00

(52) U.S. Cl. 365/148

(57) ABSTRACT

A one time programmable phase change memory may include an array of phase change memory cells. Because the array is one time programmable, users may provide the manufacturer with code to be pre-programmed into the array. The memory may be programmed, for example, by fusing one or more cells to exhibit the desired memory state.

### BACKGROUND

This invention relates generally to phase change memories.

Phase change memory devices use phase change materials, i.e., materials that may be electrically switched between a generally amorphous and a generally crystalline state, as an electronic memory. One type of memory element utilizes a phase change material that may be, in one application, electrically switched between generally amorphous and generally crystalline local orders or between the different detectable states of local order across the entire spectrum between completely amorphous and completely crystalline states.

Typical materials suitable for such an application include various chalcogenide elements. The state of the phase change materials is also non-volatile. When the memory is set in either a crystalline, semi-crystalline, amorphous, or semi-amorphous state representing a resistance value, that value is retained until reprogrammed, even if power is removed. This is because the program value represents a phase or physical state of the memory (e.g., crystalline or amorphous).

Thus, there is a need for alternate ways to provide phase change memories.

### BRIEF DESCRIPTION OF THE DRAWINGS

FIG. 1 is a schematic depiction of one embodiment of the present invention;

FIG. 2 is a schematic depiction of a portion of an array in one embodiment of the present invention;

FIG. 3 is a schematic and cross-sectional view of a cell in accordance with one embodiment of the present invention;

FIG. 4 is a schematic and cross-sectional view of the cell in another condition in one embodiment of the present invention; and

FIG. 5 is a system depiction of one embodiment of the present invention.

### DETAILED DESCRIPTION

As used herein, “one time programmable” means that at least some bits or cells in a memory array are either not reprogrammable by the user or that something is done to make it more difficult for most users to reprogram those cells or bits. Typically, a customer may send the manufacturer a tape with the information to be programmed into the one time programmable memory. With conventional one time programmable memories, preparing a mask for mask programming may involve an expensive tooling cost.

In the manufacture of phase change memories, certain processing steps, including the steps involved in packaging a phase change memory die, may adversely affect the programmed state of some bits. Generally, the bits may be initially programmed to one state, such as the reset state. Temperature exposure during packaging (or at other times after manufacture) may change the reset bits to the set state. Thus, if the memory in the die form was conventionally programmed in the factory, a one-time programmable functionality would not be feasible.

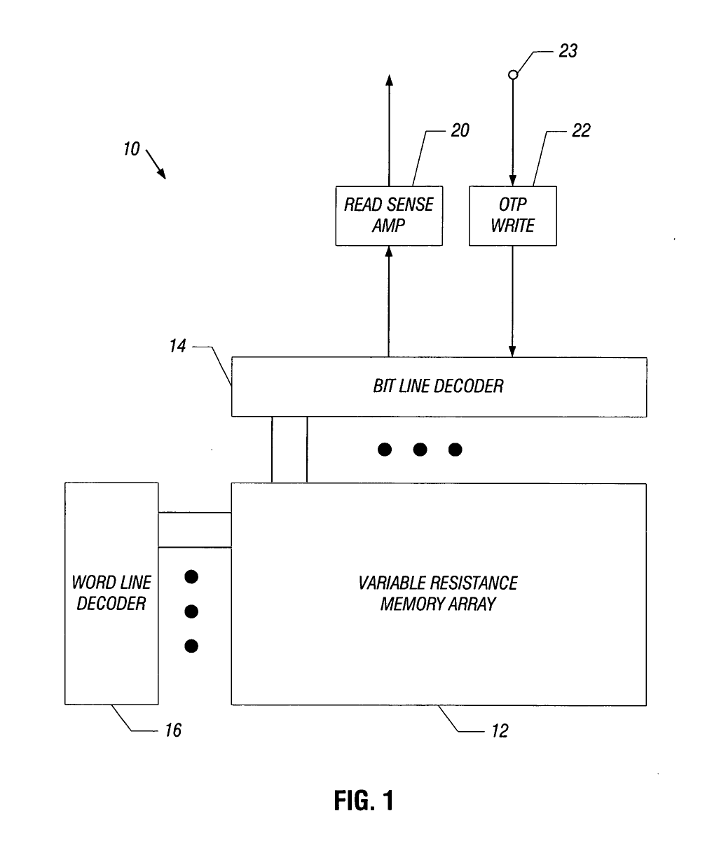

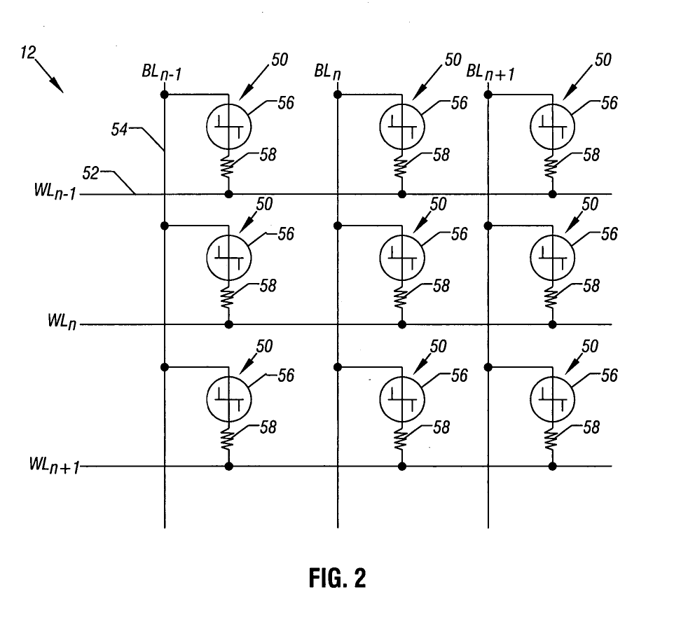

Referring to FIG. 1, a memory 10 may include a variable resistance memory array 12. The memory 10, in one embodiment, may be a one time programmable (OTP) phase change memory. The variable resistance memory array 12 may include a plurality of cells 50 arranged in rows and columns as shown in FIG. 2. The cells 50 may include a phase change memory element 56 and a selection device 58 in one embodiment. In one embodiment, a cell 50 may be associated with a word line 52, addressable by a word line decoder 16, shown in FIG. 1, and a bit line or column line 54, addressable by a bit line decoder 14, shown in FIG. 1.

A read sense amplifier 20, and an OTP write interface 22 may be coupled to the bit line decoder 14. The write interface 22 provides signals to the bit line decoder 14. Those signals may be utilized to permanently program selected cells within the array 12. A cell 50 may be selectively, permanently programmed to a desired resistance value to thereby determine and permanently store reusable code.

In order to implement a one time programmable device in one embodiment of the present invention, the pin 23 coupled to the OTP write interface 22 may be made inaccessible at any time after shipping. For example, the pin 23 may not be bonded out. The pin 23 may still be contacted by the manufacturer before packaging but cannot readily be contacted or used by the user after packaging. For example, a lead or solder bump on the package may be clipped before the part is shipped to the customer. Other techniques for forming one time programmable devices are also incorporated herein, including other techniques set forth hereinafter.

Another way to make a one time programmable memory is to program the memory before packaging. Pre-packaged programming may be done at very little cost. Then the ensuing packaging steps may be done at sufficiently low temperature to avoid changing the state of the programmed bits.

As still another alternative, a relatively high voltage or current may be used to effectively fix a bit in one programmed state. This may be done by causing a total or partial fusing of the bit. Coming out of the fab, the programmable memory cell material is in the lower resistance or set state. In a total fusion, a hole is effectively formed where the cell formerly was situated. In the partial fusion, the phase change material may be partially or completely mixed with at least one electrode associated with that phase change material, changing the composition of the programmable memory cell material so it is no longer capable of phase change upon application of a higher temperature and preferably leaving the cell in the higher resistance or reset state.

With any of these approaches, the customers then receive the part ready to use and do not need to undertake the relatively costly and awkward process of programming each chip after the chip has been packaged. Moreover, expensive tooling may be needed at the fabrication facility for programming the one time programmable memory. Also, special voltages and currents may need to be applied to chip using pads that are more conveniently accessed at wafer probe.

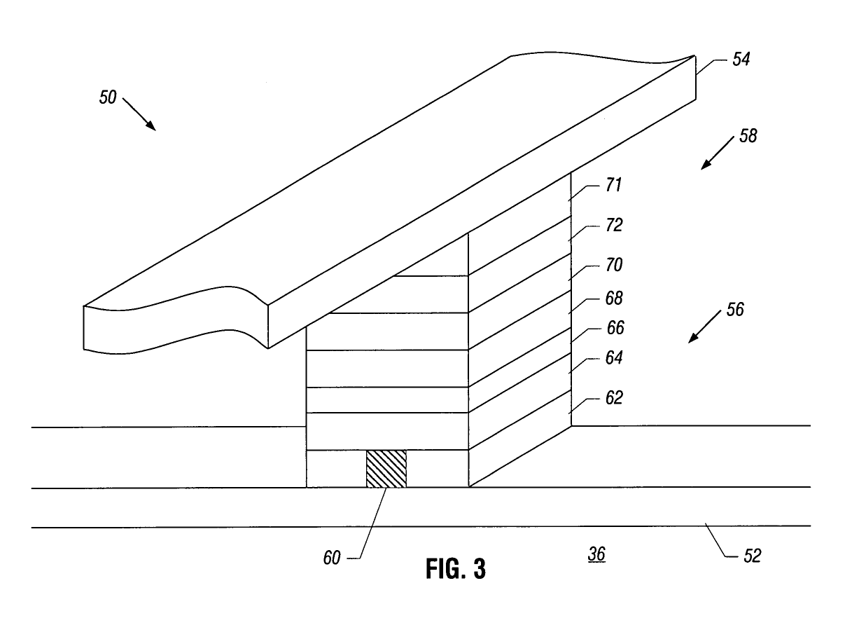

Referring to FIG. 3, a cell 50 in the array 12 may be formed over a substrate 36. The substrate 36, in one embodiment, may include the conductive word line 52 coupled to a selection device 58. The selection device 58, in one embodiment, may be formed in the substrate 36 and may, for example, be a diode, transistor, or a device using a non-programmable chalcogenide selection device.

The selection device 58 may be formed of a non-programmable chalcogenide material including a top electrode 71, a chalcogenide material 72, and a bottom electrode 70. The selection device 58 may be permanently in the reset state in one embodiment. While an embodiment is illustrated in which the selection device 58 is positioned over the phase change memory element 56, the opposite orientation may be used as well.

Conversely, the phase change memory element 56, prior to one time programming, may be capable of assuming either a set or reset state, explained in more detail hereinafter. The phase change memory element 56 may include an insulator 62, a phase change memory material 64, a top electrode 66, and a barrier film 68, in one embodiment of the present invention. A lower electrode 60 may be defined within the insulator 62 in one embodiment of the present invention.

In one embodiment, the phase change material 64 may be a phase change material suitable for non-volatile memory data storage. A phase change material may be a material having electrical properties (e.g., resistance) that may be changed through the application of energy such as, for example, heat, light, voltage potential, or electrical current.

Examples of phase change materials may include a chalcogenide material or an ovonic material. An ovonic material may be a material that undergoes electronic or structural changes and acts as a semiconductor once subjected to application of a voltage potential, electrical current, light, heat, etc. A chalcogenide material may be a material that includes at least one element from column VI of the periodic table or may be a material that includes one or more of the chalcogen elements, e.g., any of the elements of tellurium, sulfur, or selenium. Ovonic and chalcogenide materials may be non-volatile memory materials that may be used to store information.

In one embodiment, the memory material 64 may be chalcogenide element composition from the class of tellurium-germanium-antimony (TeₓGe_{y}Sb_{z}) material or a GeSbTe alloy, although the scope of the present invention is not limited to just these materials.

In one embodiment, if the memory material 64 is a non-volatile, phase change material, the memory material may be programmed into one of at least two memory states by applying an electrical signal to the memory material. An electrical signal may alter the phase of the memory material between a substantially crystalline state and a substantially amorphous state, wherein the electrical resistance of the memory material 64 in the substantially amorphous state is greater than the resistance of the memory material in the substantially crystalline state. Accordingly, in this embodiment, the memory material 64 may be adapted to be altered to a particular one of a number of resistance values within a range of resistance values to provide digital or analog storage of information.

Programming of the memory material to alter the state or phase of the material may be accomplished by applying voltage potentials to the lines 52 and 54, thereby generating a voltage potential across the memory material 64. An electrical current may flow through a portion of the memory material 64 in response to the applied voltage potentials, and may result in heating of the memory material 64.

This heating and subsequent cooling may alter the memory state or phase of the memory material 64. Altering the phase or state of the memory material 64 may alter an electrical characteristic of the memory material 64. For example, resistance of the material 64 may be altered by altering the phase of the memory material 64. The memory material 64 may also be referred to as a programmable resistive material or simply a programmable resistance material.

In one embodiment, a voltage potential difference of about 0.5 to 1.5 volts may be applied across a portion of the memory material by applying about 0 volts to a line 52 and about 0.5 to 1.5 volts to an upper line 54. A current flowing through the memory material 64 in response to the applied voltage potentials may result in heating of the memory material. This heating and subsequent cooling may alter the memory state or phase of the material.

In a “reset” state, the memory material may be in an amorphous or semi-amorphous state and in a “set” state, the memory material may be in a crystalline or semi-crystalline state. The resistance of the memory material in the amorphous or semi-amorphous state may be greater than the resistance of the material in the crystalline or semi-crystalline state. The association of reset and set with amorphous and crystalline states, respectively, is a convention. Other conventions may be adopted.

Due to electrical current, the memory material 64 may be heated to a relatively higher temperature to amorphisize memory material and “reset” memory material. Heating the volume or memory material to a relatively lower crystallization temperature may crystallize memory material and “set” memory material. Various resistances of memory material may be achieved to store information by varying the amount of current flow and duration through the volume of memory material, or by tailoring the edge rate of the trailing edge of the programming current or voltage pulse.

The information stored in memory material 64 may be read by measuring the resistance of the memory material. As an example, a read current may be provided to the memory material using opposed lines 54, 52 and a resulting read voltage across the memory material may be compared against a reference voltage using, for example, the sense amplifier 20. The read voltage may be proportional to the resistance exhibited by the memory storage element.

In order to select a cell 50 on column 54 and row 52, the selection device 58 for the selected cell 50 at that location may be operated. The selection device 58 activation allows current to flow through the memory element 56 in one embodiment of the present invention.

In a low voltage or low field regime A, the device 58 is off and may exhibit very high resistance in some embodiments. The off resistance can, for example, range from 100,000 ohms to greater than 10 gigaohms at a bias of half the threshold voltage. The device 58 may remain in its off state until a threshold voltage V_{T} or threshold current I_{T} switches the device 58 to a highly conductive, low resistance on state. The voltage across the device 58 after turn on drops to a slightly lower voltage, called the holding voltage V_{H} and remains very close to the threshold voltage. In one embodiment of the present invention, as an example, the threshold voltage may be on the order of 1.1 volts and the holding voltage may be on the order of 0.9 volts.

After passing through the snapback region, in the on state, the device 58 voltage drop remains close to the holding voltage as the current passing through the device is increased up to a certain, relatively high, current level. Above that current level the device remains on but displays a finite differential resistance with the voltage drop increasing with increasing current. The device 58 may remain on until the current through the device 58 is dropped below a characteristic holding current value that is dependent on the size and the material utilized to form the device 58.

In some embodiments of the present invention, the selection device 58 does not change phase. It remains permanently amorphous and its current-voltage characteristics may remain the same throughout its operating life.

As an example, for a 0.5 micrometer diameter device 58 formed of TeAsGeSSe having respective atomic percents of 16/13/15/1/55, the holding current may be on the order of 0.1 to 100 micro-ohms in one embodiment. Below this holding current, the device 58 turns off and returns to the high resistance regime at low voltage, low field. The threshold current for the device 58 may generally be of the same order as the holding current. The holding current may be altered by changing process variables, such as the top and bottom electrode material and the chalcogenide material. The device 58 may provide high “on current” for a given area of device compared to conventional access devices such as metal oxide semiconductor field effect transistors or bipolar junction transistors.

In some embodiments, the higher current density of the device 58 in the on state allows for higher programming current available to the memory element 56. Where the memory element 56 is a phase change memory, this enables the use of larger programming current phase change memory devices, reducing the need for sub-lithographic feature structures and the commensurate process complexity, cost, process variation, and device parameter variation.

One technique for addressing the array 12 uses a voltage V applied to the selected column and a zero voltage applied to the selected row. For the case where the device 56 is a phase change memory, the voltage V is chosen to be greater than the device 58 maximum threshold voltage plus the memory element 56 reset maximum threshold voltage, but less than two times the device 58 minimum threshold voltage. In other words, the maximum threshold voltage of the device 58 plus the maximum reset threshold voltage of the device 56 may be less than V and V may be less than two times the minimum threshold voltage of the device 58 in some embodiments. All of the unselected rows and columns may be biased at V/2.

With this approach, there is no bias voltage between the unselected rows and unselected columns. This reduces background leakage current.

After biasing the array in this manner, the memory elements 56 may be programmed and read by whatever means is needed for the particular memory technology involved. A memory element 56 that uses a phase change material may be programmed by forcing the current needed for memory element phase change or the memory array can be read by forcing a lower current to determine the device 56 resistance.

For the case of a phase change memory element 56, programming a given selected bit in the array 12 can be as follows. Unselected rows and columns may be biased as described for addressing. Zero volts is applied to the selected row. A current is forced on the selected column with a compliance that is greater than the maximum threshold voltage of the device 58 plus the maximum threshold voltage of the device 56. The current amplitude, duration, and pulse shape may be selected to place the memory element 56 in the desired phase and thus, the desired memory state.

Reading a phase change memory element 56 can be performed as follows. Unselected rows and columns may be biased as described previously. Zero volts is applied to the selected row. A voltage is forced at a value greater than the maximum threshold voltage of the device 58, but less than the minimum threshold voltage of the device 58 plus the minimum threshold voltage of the element 56 on the selected column. The current compliance of this forced voltage is less than the current that could program or disturb the present phase of the memory element 56. If the phase change memory element 56 is set, the access device 58 switches on and presents a low voltage, high current condition to a sense amplifier. If the device 16 is reset, a larger voltage, lower current condition may be presented to the sense amplifier. The sense amplifier can either compare the resulting column voltage to a reference voltage or compare the resulting column current to a reference current.

The above-described reading and programming protocols are merely examples of techniques that may be utilized. Other techniques may be utilized by those skilled in the art.

To avoid disturbing a set bit of memory element 56 that is a phase change memory, the peak current may equal the threshold voltage of the device 58 minus the holding voltage of the device 58 that quantity divided by the total series resistance including the resistance of the device 58, external resistance of device 56, plus the set resistance of device 56. This value may be less than the maximum programming current that will begin to reset a set bit for a short duration pulse.

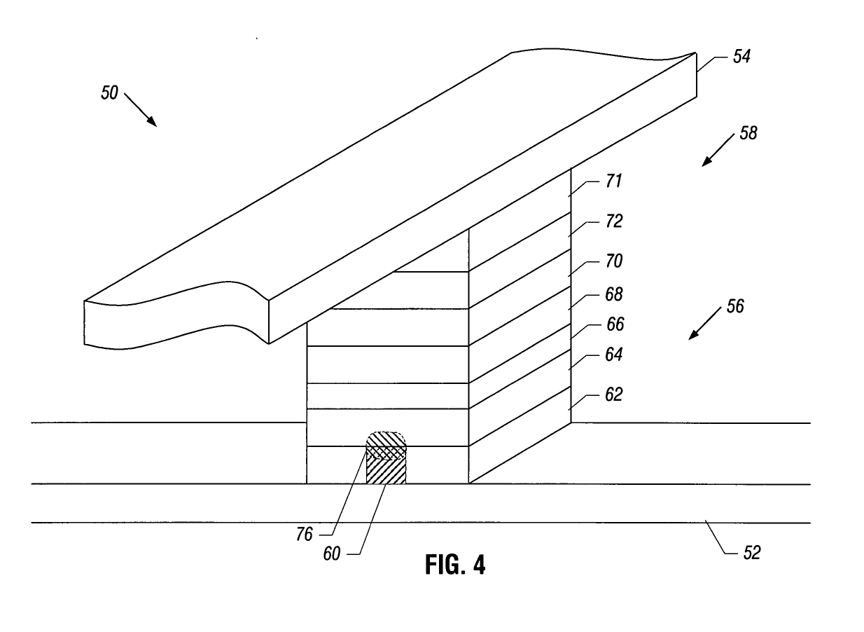

Referring next to FIG. 4, the memory element 56 may be completely or partially fused by applying a relatively higher voltage or relatively higher current than is utilized in connection with regular programming of the element 56. In response to the application of a higher current or voltage, the region 76 may become partially or completely fused. That is, the material of the electrode 60 may mix into the phase change material 64 to form the region 76 of intermixed material. Because of this mixing of conductor and phase change material, the cell may be permanently programmed in the reset state. Subsequent heating may have no effect on the cell.

Alternatively, a sufficiently high current or voltage may be applied so that the region 76 is the effectively blown. No current then will pass because an open circuit has been formed. Again, a reset state is permanently established.

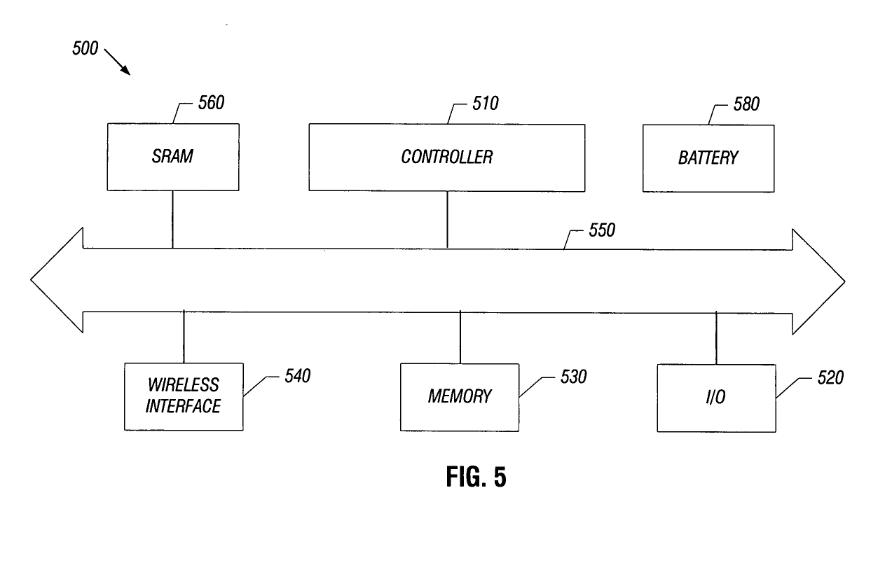

Turning to FIG. 5, a portion of a system 500 in accordance with an embodiment of the present invention is described. System 500 may be used in wireless devices such as, for example, a personal digital assistant (PDA), a laptop or portable computer with wireless capability, a web tablet, a wireless telephone, a pager, an instant messaging device, a digital music player, a digital camera, or other devices that may be adapted to transmit and/or receive information wirelessly. System 500 may be used in any of the following systems: a wireless local area network (WLAN) system, a wireless personal area network (WPAN) system, or a cellular network, although the scope of the present invention is not limited in this respect.

System 500 may include a controller 510, an input/output (I/O) device 520 (e.g. a keypad, display), a memory 530, a wireless interface 540, and a static random access memory (SRAM) 560 and coupled to each other via a bus 550. A battery 580 may supply power to the system 500 in one embodiment. It should be noted that the scope of the present invention is not limited to embodiments having any or all of these components.

Controller 510 may comprise, for example, one or more microprocessors, digital signal processors, micro-controllers, or the like. Memory 530 may be used to store messages transmitted to or by system 500. Memory 530 may also optionally be used to store instructions that are executed by controller 510 during the operation of system 500, and may be used to store user data. The instructions may be stored as digital information and the user data, as disclosed herein, may be stored in one section of the memory as digital data and in another section as analog memory. As another example, a given section at one time may be labeled as such and store digital information, and then later may be relabeled and reconfigured to store analog information. Memory 530 may be provided by one or more different types of memory. For example, memory 530 may comprise a volatile memory (any type of random access memory), a non-volatile memory such as a flash memory, and/or phase change memory that includes a memory element such as, for example, memory 10 illustrated in FIG. 1.

The I/O device 520 may be used to generate a message. The system 500 may use the wireless interface 540 to transmit and receive messages to and from a wireless communication network with a radio frequency (RF) signal. Examples of the wireless interface 540 may include an antenna, or a wireless transceiver, such as a dipole antenna, although the scope of the present invention is not limited in this respect. Also, the I/O device 520 may deliver a voltage reflecting what is stored as either a digital output (if digital information was stored), or it may be analog information (if analog information was stored).

While an example in a wireless application is provided above, embodiments of the present invention may also be used in non-wireless applications as well.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
forming a one time programmable phase change memory.

2. The method of claim 1 including permanently fusing at least one cell of the phase change memory array.

3. The method of claim 2 including forming an open circuit at said cell.

4. The method of claim 2 including forming a cell containing phase change material and a conductor and causing said phase change material and said conductor to mix.

5. The method of claim 2 wherein permanently programming said cell includes applying a relatively high current to the cell.

6. The method of claim 1 including programming a phase change memory and thereafter limiting exposure to a temperature that would change a stored state of said cell of said phase change memory.

7. The method of claim 1 including forming a phase change memory having a plurality of cells arranged in rows and columns.

8. The method of claim 7 including forming a cell including a phase change memory element and a selection device coupled in series.

9. The method of claim 8 including forming a permanently programmed phase change memory selection device.

10. The method of claim 7 including forming an array coupled to a pair of decoders, and coupling said decoders to a write interface, said write interface coupled to a write pin.

11. The method of claim 10 including packaging said memory so that said write pin is inaccessible to the user.

12. A memory comprising:
a one time programmable phase change memory array; and
read circuitry coupled to said array.

13. The memory of claim 12 wherein said array includes at least one cell that is permanently set in one memory state.

14. The memory of claim 13 wherein said cell is an open circuit.

15. The memory of claim 13 wherein said cell includes a phase change memory material and a conductor, said conductor and said memory material being intermixed.

16. The memory of claim 13 wherein said cell includes a phase change memory element and a selection device coupled in series.

17. The memory of claim 16 wherein said selection device is a permanently programmed phase change memory selection device.

18. The memory of claim 16 wherein said memory element is programmable to one of at least two states.

19. The memory of claim 13 wherein said memory includes a pair of decoders, said decoders coupled to a write interface, said write interface coupled to a write pin.

20. The memory of claim 19 wherein said memory is packaged so that said write pin is inaccessible to the user.

21. A system comprising:
a processor;
a static random access memory coupled to said processor; and
a one time programmable phase change memory coupled to said processor.

22. The system of claim 21 wherein said one time programmable phase change memory includes a memory array with at least one cell that is permanently set in one memory state.

23. The system of claim 22 wherein said cell is an open circuit.

24. The system of claim 22 wherein said cell includes a phase change memory material and a conductor, said conductor and said memory material being intermixed.

25. The system of claim 22 wherein said cell includes a phase change memory element and a selection device coupled in series.

26. The system of claim 25 wherein said selection device is a permanently programmed phase change memory selection device.

27. The system of claim 25 wherein said memory element is programmable to one of at least two states.

28. The system of claim 22 wherein said phase change memory includes a pair of decoders, said decoders coupled to a write interface, said write interface coupled to a write pin.

29. The system of claim 28 wherein said phase change memory is packaged so that said write pin is inaccessible to the user.

30. A memory comprising:
a memory array including a plurality of addressable cells; and
at least one cell including a phase change memory element whose programmed state cannot be changed by the user.

31. The memory of claim 30 wherein said at least one cell is permanently set in one memory state.

32. The memory of claim 31 wherein said memory element is an open circuit.

33. The memory of claim 31 wherein said memory element includes a phase change memory material and a conductor, said conductor and said memory material being intermixed.

34. The memory of claim 31 including a selection device coupled in series with said phase change memory element.

35. The memory of claim 34 wherein said selection device is a permanently programmed phase change memory selection device.

36. The memory of claim 34 wherein said memory element is programmable to one of at least two states.

37. The memory of claim 31 including a pair of decoders, said decoders coupled to a write interface, said write interface coupled to a write pin.

38. The memory of claim 37 wherein said memory is packaged so that said write pin is inaccessible to the user.
